(19) United States
(12) Patent Application Publication
(10) Pub. No.: US 2021/0292473 A1
(43) Pub. Date: Sep. 23, 2021

(54) EPOXY RESIN COMPOSITION AND RESIN-ENCAPSULATED SUBSTRATE

(71) Applicant: Panasonic Intellectual Property Management Co., Ltd., Osaka (JP)

(72) Inventors: Takahiro AKASHI, Hyogo (JP); Toshiyuki MAKITA, Mie (JP)

(73) Assignee: Panasonic Intellectual Property Management Co., Ltd., Osaka (JP)

(21) Appl. No.: 17/262,547

(22) PCT Filed: Jun. 28, 2019
(86) PCT No.: PCT/JP2019/025831

§ 371 Date: Jan. 22, 2021

(30) Foreign Application Priority Data
Jul. 26, 2018 (JP) 2018-140627

(51) Int. Cl. C08G 59/62; C08G 59/22; C08K 3/36; C08K 7/18; C08L 63/00; H05K 1/18; H05K 3/28

(52) U.S. Cl. CPC C08G 59/621; C08G 59/22; C08K 3/36; C08L 2203/206; C08L 63/00; H05K 1/181; H05K 3/284; C08K 7/18

(57) ABSTRACT

An epoxy resin composition contains an epoxy resin and a curing agent. The epoxy resin includes an epoxy resin expressed by the following Formula (1),

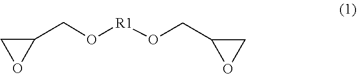

where R1 represents a divalent organic group having a carbon number of two or more. Content of the epoxy resin expressed by Formula (1) with respect to a total mass of the epoxy resin is 50% by mass or more. The curing agent contains a phenolic resin expressed by the following Formula (2):

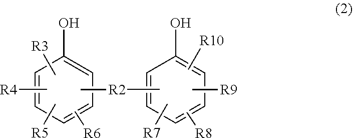

where R2 represents a divalent organic group having a carbon number of one or more and R3-R10 each independently represent a hydrogen atom, a hydroxyl group, or an allyl group.

### TECHNNICAL FIELD

The present disclosure generally relates to an epoxy resin composition and a resin-encapsulated substrate, and more particularly relates to an epoxy resin composition containing an epoxy resin and a curing agent and a resin-encapsulated substrate.

### BACKGROUND ART

Patent Literature 1 discloses a low-gloss thermosetting epoxy resin composition. The low-gloss thermosetting epoxy resin composition contains: an epoxy resin including two or more epoxy groups per molecule; an epoxy resin curing agent; an inorganic filler; and thermoplastic resin particles exhibiting solid phase at 25° C.

Meanwhile, Patent Literature 2 discloses an encapsulating epoxy resin-inorganic filler composite sheet. The encapsulating epoxy resin-inorganic filler composite sheet is formed in a semi-cured state by applying an epoxy resin composition, including, as essential components, an epoxy resin, a curing agent, and an inorganic filler, onto the surface of a carrier member and heating and drying the epoxy resin composition.

Research and development in the field of wearable devices has been increasingly activated recently. However, the low-gloss thermosetting epoxy resin composition of Patent Literature 1 and the encapsulating epoxy resin-inorganic filler composite sheet of Patent Literature 2 are both difficult to be applied to those wearable devices in terms of flexibility and stretchability.

### CITATION LIST

### Patent Literature

Patent Literature 1: JP 2018-035292A

Patent Literature 1: JP 2014-095063 A

### SUMMARY OF INVENTION

It is therefore an object of the present disclosure to provide an epoxy resin composition and a resin-encapsulated substrate contributing to making a molded product with excellent flexibility and stretchability.

An epoxy resin composition according to an aspect of the present disclosure contains an epoxy resin and a curing agent. The epoxy resin includes an epoxy resin expressed by the following Formula (1):

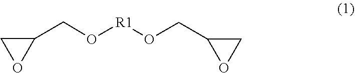

where R1 represents a divalent organic group having a carbon number of two or more. Content of the epoxy resin expressed by Formula (1) with respect to a total mass of the epoxy resin is 50% by mass or more.

The curing agent contains a phenolic resin expressed by the following Formula (2):

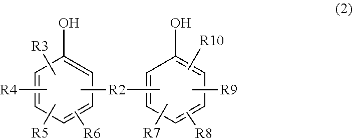

where R2 represents a divalent organic group having a carbon number of one or more and R3-R10 each independently represent a hydrogen atom, a hydroxyl group, or an allyl group.

A resin-encapsulated substrate according to another aspect of the present disclosure includes: a substrate; an electronic component mounted on the substrate; and an encapsulating resin layer to encapsulate the electronic component. The encapsulating resin layer is a molded product of the epoxy resin composition described above.

### BRIEF DESCRIPTION OF DRAWINGS

FIG. 1 is a perspective view of a resin-encapsulated substrate according to an exemplary embodiment of the present disclosure; and

FIG. 2 is a schematic cross-sectional view of the resin-encapsulated substrate.

### DESCRIPTION OF EMBODIMENTS

1. Overview

An epoxy resin composition according to an exemplary embodiment contains an epoxy resin and a curing agent.

The epoxy resin includes an epoxy resin expressed by the following Formula (1):

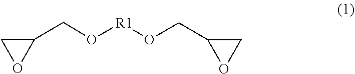

where R1 represents a divalent organic group having a carbon number of two or more. The content of the epoxy resin expressed by the Formula (1) with respect to a total mass of the epoxy resin is 50% by mass or more.

The curing agent contains a phenolic resin expressed by the following Formula (2):

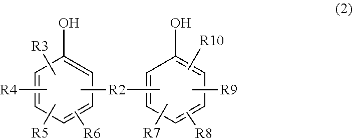

where R2 represents a divalent organic group having a carbon number of one or more and R3-R10 each independently represent a hydrogen atom, a hydroxyl group, or an allyl group.

An epoxy resin composition according to this embodiment contributes to providing a molded product with excellent flexibility and stretchability by combining the epoxy resin expressed by the Formula (1) with the phenolic resin expressed by the Formula (2).

2. Details

2.1. Epoxy Resin Composition

An epoxy resin composition according to this embodiment includes an epoxy resin and a curing agent. The epoxy resin composition is in liquid phase at an ordinary temperature.

The epoxy resin is a prepolymer (also called a “low polymer” or an “oligomer”). Specifically, the epoxy resin includes an epoxy resin expressed by the following Formula (1).

In Formula (1), R1 represents a divalent organic group having a carbon number of two or more and may form a principal chain. From the point of view of flowability of the epoxy resin composition during molding, the carbon number of R1 is suitably 100 or less and more suitably 50 or less. If the carbon number of R1 were one, then the molded product might be unable to exhibit stretchability.

The divalent organic group may be a methylene straight chain, for example. The methylene straight chain has a structure in which two or more methylene groups are bonded together in series. At least some hydrogen atoms of the methylene straight chain may be replaced with a substituent such as an alkyl group having a carbon number of 1 to 20. The principal chain may include a benzene ring. To improve the flexibility and stretchability of the molded product, the longer R1 is, the better.

The epoxy resin expressed by Formula (1) is a compound with two epoxy groups per molecule. The two epoxy groups are bonded one by one to both ends of the principal chain. R1 suitably includes no epoxy groups. The absence of epoxy groups from the R1 part prevents any part other than both ends of the principal chain from crosslinking, thus reducing the chances of the flexibility and stretchability of the molded product being impaired.

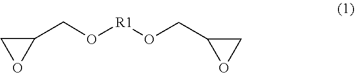

where R1 represents a divalent organic group having a carbon number of two or more.

R1 suitably includes no siloxane bonds. This curbs a decline in adhesiveness between the encapsulating resin layer 4, which is a molded product of the epoxy resin composition, and the substrate 2 and the electronic component 3 in the resin-encapsulated substrate 1 (see FIG. 2).

The epoxy resin may include an epoxy resin other than the one expressed by Formula (1) (hereinafter referred to as “additional epoxy resin(s)”). Specific examples of the additional epoxy resins include a bisphenol A type epoxy resin, a bisphenol F type epoxy resin, a bisphenol A/D type epoxy resin, and a biphenyl type epoxy resin.

If the epoxy resin includes an additional epoxy resin, then the content of the epoxy resin expressed by the Formula (1) is at least 50% by mass, suitably 70% by mass or more, with respect to the total mass of the epoxy resin. If the content of the epoxy resin expressed by Formula (1) were less than 50% by mass, then it could be impossible to impart flexibility or stretchability to the molded product. For example, if the additional epoxy resin has a rigid skeleton, then the effect of imparting flexibility and stretchability by the epoxy resin expressed by Formula (1) would be affected significantly and diminished by the rigidity, thus possibly making the molded product too rigid and brittle.

The curing agent includes a phenolic resin expressed by the following Formula (2), where R2 is a divalent organic group having a carbon number of at least one, suitably 1 to 100, more suitably 1 to 50, and may form a principal chain. The divalent organic group may be a methylene straight chain, for example. At least some hydrogen atoms of the methylene straight chain may be replaced with a substituent such as an alkyl group. The principal chain may include a benzene ring. To improve the flexibility and stretchability of the molded product, the longer R2 is, the better.

The phenolic resin expressed by Formula (2) is a compound including two or more phenolic hydroxyl groups per molecule and suitably including at least one allyl group, more suitably two or more allyl groups, per molecule. At least two phenolic hydroxyl groups are bonded one by one to both ends of the principal chain. If the phenolic resin includes two or more allyl groups, at least one allyl group is suitably bonded to each of the two ends of the principal chain. Those allyl groups bonded to both ends of the principal chain would presumably contribute to improving the flexibility and stretchability of the molded product.

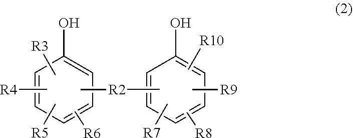

where R2 represents a divalent organic group having a carbon number of one or more and R3-R10 each independently represent a hydrogen atom, a hydroxyl group, or an allyl group.

The phenolic resin expressed by Formula (2) suitably includes no siloxane bonds. This curbs a decline in adhesiveness between the encapsulating resin layer 4, which is a molded product of the epoxy resin composition, and the substrate 2 and the electronic component 3 in the resin-encapsulated substrate 1 (see FIG. 2).

R2 suitably includes no epoxy groups. The absence of epoxy groups from the R2 part prevents any part other than both ends of the principal chain from crosslinking, thus reducing the chances of the flexibility and stretchability of the molded product being impaired.

The curing agent may include a curing agent other than the phenolic resin expressed by Formula (2) (hereinafter referred to as “additional curing agent(s)”). Specific examples of the additional curing agents include acid anhydrides, amines, and phenol novolac resins.

The stoichiometric equivalent ratio (curing agent/epoxy resin) of the curing agent to the epoxy resin suitably falls within the range from 0.5 to 2.0.

The epoxy resin composition suitably further contains an inorganic filler. This imparts moisture resistance to the molded product. That is to say, this reduces the chances of the molded product absorbing moisture. The moisture resistance may be evaluated by moisture vapor transmission rate, for example. Specific examples of the inorganic filler include fused silica, crystalline silica, and alumina. From the point of view of the flowability of the epoxy resin composition during molding, fused silica is preferred.

If the epoxy resin composition further contains an inorganic filler, then the content of the inorganic filler is suitably 70% by mass or less with respect to the total mass of the epoxy resin composition. Setting the content of the inorganic filler at 70% by mass or less allows the moisture resistance of the molded product to be increased with the flexibility and stretchability of the molded product maintained. In addition, setting the content of the inorganic filler at 70% by mass or less reduces an increase in the viscosity of the epoxy resin composition and allows the epoxy resin composition to maintain its flowability. This enables even a narrow gap to be easily filled with the epoxy resin composition. That is to say, this makes the epoxy resin composition usable as an underfilling material for forming the encapsulating resin layer 4 that fills the gap between the substrate 2 and the electronic components 3 (see FIG. 2). The lower limit of the content of the inorganic filler is not limited to any particular value but may be 1% by mass, for example.

The epoxy resin composition may further contain a curing accelerator. Specific examples of the curing accelerators include 2-ethyl-4-methylimidazole, nitrogen-containing compounds, and phosphorus compounds.

The epoxy resin composition may be prepared by mixing the epoxy resin and the curing agent in an appropriate mixer, adding the inorganic filler and curing accelerator as needed to the mixture, and then stirring up the mixture thus obtained.

The epoxy resin composition suitably has a viscosity of 100 Pa·s or less, more suitably 20 Pa·s or less. This increases the flowability of the epoxy resin composition to the point of making the epoxy resin composition effectively usable as an underfilling material. This reduces the chances of voids being produced in the encapsulating resin layer 4 while the encapsulating resin layer 4 is formed by filling the gap between the substrate 2 and the electronic components 3 with the epoxy resin composition. Note that the viscosity herein refers to a viscosity at room temperature (25° C.).

The molded product of the epoxy resin composition is obtained by heating the epoxy resin composition to cause a curing reaction. The molded product thus obtained has excellent flexibility. That is to say, the molded product is easily foldable and hardly cracks even when folded. In addition, the molded product also has excellent stretchability. That is to say, the molded product is easily stretchable and shrinkable and easily recovers its original shape even when stretched or shrunken. As can be seen, the epoxy resin composition according to this embodiment allows a molded product with excellent flexibility and stretchability to be obtained.

The molded product of the epoxy resin composition suitably has a breaking elongation of at least 30%, more suitably 100% or more, and even more suitably 300% or more. Setting the breaking elongation at 30% or more reduces the chances of the molded product as the encapsulating resin layer 4 impairing the properties of the substrate 2 when the encapsulating resin layer 4 is integrated with the substrate 2 with flexibility and stretchability, for example. That is to say, this makes the encapsulating resin layer 4, as well as the substrate 2, foldable, stretchable, and shrinkable.

In this case, the breaking elongation described above is obtained by carrying out a tensile test. When the tensile test is carried out, a test specimen is formed out of the epoxy resin composition, two gauge lines are drawn parallel to each other on the test specimen, and then the test specimen is pulled perpendicularly to these gauge lines to the point that the test specimen is broken. Then, the increase in the length between the gauge lines (hereinafter referred to as a “gauge length”) is divided by the initial gauge length (of 25 mm, for example) to obtain a breaking elongation. The increase in the gauge length is the difference between the gauge length after the test specimen has been broken and the initial gauge length. The gauge length after the test specimen has been broken is measured by rejoining the broken pieces of the test specimen together. The upper limit of the breaking elongation of the molded product of the epoxy resin composition is not limited to any particular value but may be 500%, for example.

The epoxy resin composition is suitably used to encapsulate the electronic components 3 mounted on the substrate 2. That is to say, the epoxy resin composition is suitably used as a liquid encapsulant. Enabling resin encapsulation to be done with a liquid encapsulant using a relatively inexpensive facility makes it easier to apply the resin composition to a broadening variety of implementations. Thus, the resin composition according to this embodiment is suitably applicable to manufacturing multiple types of products in small quantities.

2.2. Resin-encapsulated Substrate

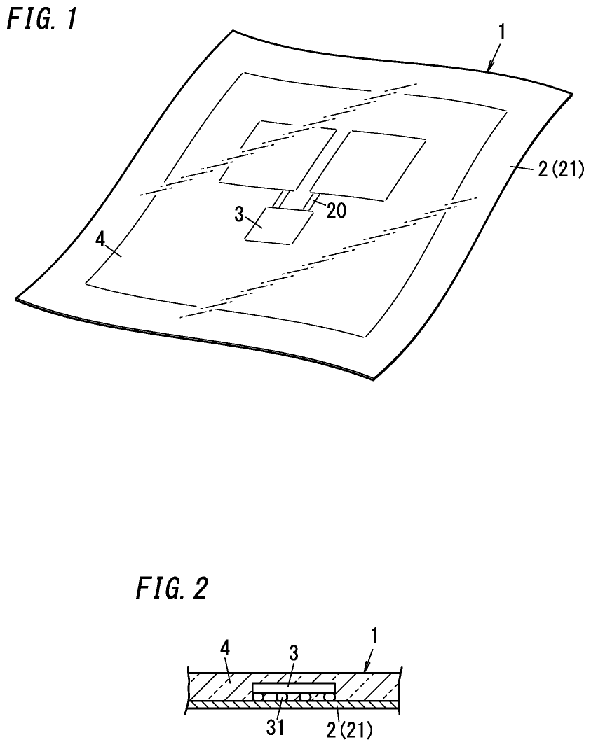

FIG. 1 illustrates a resin-encapsulated substrate 1 according to this embodiment. The resin-encapsulated substrate 1 has the shape of a film or a sheet. The resin-encapsulated substrate 1 includes a substrate 2, electronic components 3, and an encapsulating resin layer 4.

The substrate 2 has electrical insulation properties. The thickness, planar shape, dimensions, and material of the substrate 2 are not particularly limited. Conductor wiring 20 is formed on the surface of the substrate 2. The conductor wiring 20 may be made of electrically conductive paste, for example.

The substrate 2 is suitably implemented as a stretchable resin film 21. The stretchable resin film 21 is a film with flexibility and stretchability. The stretchable resin film 21 may have a tensile elongation of 2.5× or more, for example. Implementing the substrate 2 as a stretchable resin film 21 allows the molded product to fully exert its own stretchability. Naturally, the substrate 2 may have no flexibility or stretchability as well.

The electronic components 3 are mounted on the substrate 2. The number of the electronic components 3 provided is not limited to any particular value. The electronic components 3 include activate components (such as semiconductor elements) and passive components (such as chip resistors, chip capacitors, and chip inductors). The electronic components 3 further include a package in which semiconductor elements are encapsulated. The electronic components 3 may be in contact with the substrate 2. Alternatively, the electronic components 3 may be out of contact with the substrate 2 with bumps 31 interposed between them as shown in FIG. 2. The bumps 31 electrically connect the conductive wiring 20 on the substrate 2 to the electronic components 3.

The encapsulating resin layer 4 is a molded product of the epoxy resin composition. The encapsulating resin layer 4 encapsulates the electronic components 3. More specifically, the encapsulating resin layer 4 encapsulates the electronic components 3 either entirely or only partially. As used herein, encapsulating the electronic components 3 entirely refers to encapsulating the electronic components 3 such that the electronic components 3 are completely buried in the encapsulating resin layer 4 as shown in FIG. 2. Meanwhile, encapsulating the electronic components 3 only partially herein refers to encapsulating only a region surrounding portions (such as bumps 31) where the conductor wiring 20 on the substrate 2 and the electronic components 3 are electrically connected together without encapsulating any other portions. Encapsulating the electronic components 3 either entirely or only partially in this manner allows the portions encapsulated with the encapsulating resin layer 4 (i.e., part or all of the electronic components 3) to be protected from an external environment. The encapsulating resin layer 4 suitably encapsulates the conductor wiring 20 as well. This allows the conductor wiring 20, too, to be protected from the external environment, thus reducing disconnection thereof. The thickness of the encapsulating resin layer 4 is not limited to any particular value but may fall within the range from 5 μm to 10,000 μm (=1 cm), for example.

The resin-encapsulated substrate 1 may be fabricated in the following way. First, conductor wiring 20 is formed of electrically conductive paste, for example, on the surface of a substrate 2. Next, electronic components 3 are mounted on the substrate 2 by an appropriate bonding method such as soldering. This allows the conductor wiring 20 on the substrate 2 and the electronic components 3 to be electrically connected via the bumps 31 and other members (see FIG. 2). Subsequently, the epoxy resin composition is applied to cover the electronic components 3 and the conductor wiring 20. At this time, the gap between the substrate 2 and the electronic components 3 may be filled with the epoxy resin composition without leaving voids in the gap. Thereafter, the epoxy resin composition is heated to produce a curing reaction, thereby forming an encapsulating resin layer 4. In this manner, the resin-encapsulated substrate 1 shown in FIG. 1 may be fabricated.

The resin-encapsulated substrate 1 thus obtained has excellent flexibility. That is to say, the resin-encapsulated substrate 1 is easily foldable and hardly cracks even when folded.

In addition, the resin-encapsulated substrate 1 also has excellent stretchability. That is to say, the resin-encapsulated substrate 1 is easily stretchable and shrinkable and readily recovers its original shape even when stretched or shrunken.

As can be seen, the resin-encapsulated substrate 1 according to this embodiment has excellent flexibility and stretchability. That is to say, particularly when the substrate 2 is implemented as a stretchable resin film 21, the entire resin-encapsulated substrate 1 is freely foldable and stretchable or shrinkable with the electronic components 3 protected and with the disconnection of the conductor wiring 20 and other failures reduced. This allows the resin-encapsulated substrate 1 to be placed on any of various free-form surfaces such that the resin-encapsulated substrate 1 closely follows its surface shape. Thus, this resin-encapsulated substrate 1 is applicable for use in a broad variety of fields including wearable devices, sensors, displays, and robots.

3. Aspects

As can be seen easily from the foregoing description of embodiments, the present disclosure has the following aspects. In the following description, reference signs are inserted in parentheses just for the sake of clarifying correspondence in constituent elements between the following aspects of the present disclosure and the exemplary embodiment described above.

An epoxy resin composition according to a first aspect contains an epoxy resin and a curing agent. The epoxy resin includes an epoxy resin expressed by the following Formula (1):

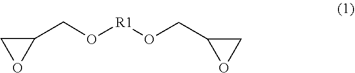

where R1 represents a divalent organic group having a carbon number of two or more. The content of the epoxy resin expressed by the Formula (1) with respect to the total mass of the epoxy resin is 50% by mass or more.

The curing agent contains a phenolic resin expressed by the following Formula (2):

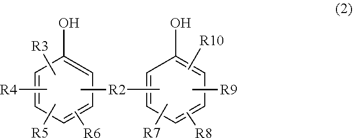

where R2 represents a divalent organic group having a carbon number of one or more and R3-R10 each independently represent a hydrogen atom, a hydroxyl group, or an allyl group.

This aspect provides a molded product with excellent flexibility and stretchability.

An epoxy resin composition according to a second aspect, which may be implemented in conjunction with the first aspect, further contains an inorganic filler.

This aspect imparts moisture resistance to the molded product.

In an epoxy resin composition according to a third aspect, which may be implemented in conjunction with the second aspect, the content of the inorganic filler with respect to the total mass of the epoxy resin composition is 70% by mass or less.

This aspect improves the moisture resistance of the molded product while maintaining the flexibility and stretchability thereof.

In an epoxy resin composition according to a fourth aspect, which may be implemented in conjunction with any one of the first to third aspects, a molded product of the epoxy resin composition has a breaking elongation of 30% or more.

This aspect reduces, when a molded product serving as an encapsulating resin layer (4) is integrated with a substrate (2) with flexibility and stretchability, the chances of the properties of the substrate (2) being impaired.

An epoxy resin composition according to a fifth aspect, which may be implemented in conjunction with any one of the first to fourth aspects, is used to encapsulate an electronic component (3) mounted on a substrate (2).

This aspect allows resin encapsulation to be done with a liquid encapsulant using a relatively inexpensive facility, thus making it easier to apply the resin composition to a broadening variety of implementations. Thus, the resin composition according to this aspect is suitably applicable to manufacturing multiple types of products in small quantities.

A resin-encapsulated substrate (1) according to a sixth aspect includes: a substrate (2); an electronic component (3) mounted on the substrate (2); and an encapsulating resin layer (4) to encapsulate the electronic component (3). The encapsulating resin layer (4) is a molded product of the epoxy resin composition according to any one of the first to fifth aspects.

This aspect allows, particularly when the substrate (2) is implemented as a stretchable resin film (21), the entire resin-encapsulated substrate (1) to be folded and stretched freely with the electronic component (3) protected and with disconnection of conductor wiring (20) reduced.

### EXAMPLES

The present disclosure will now be described specifically by way of illustrative examples. Note that the following examples are only examples of the present disclosure and should not be construed as limiting.

[Epoxy Resin Composition]

The respective components were compounded together to have the compound composition (in % by mass) shown in the following Table 1, mixed together in a planetary mixer, and then dispersed with three rolls, thereby preparing liquid epoxy resin compositions representing first to fifth examples and a first comparative example. Following are the details of the respective components:

(Epoxy Resin)
Epoxy resin 1: YX7400 manufactured by Mitsubishi Chemical Corporation, which is an epoxy resin having an epoxy equivalent of 440 g/eq and expressed by Formula (1); and
Epoxy resin 2: YDF-8170C manufactured by Nippon Steel & Sumikin Chemical, which is an epoxy resin having an epoxy equivalent of 155-165 g/eq and an epoxy resin other than the one expressed by Formula (1).

(Curing Agent)
MEH-8000H manufactured by Meiwa Plastic Industries, Ltd., which is a phenolic resin having a hydroxyl equivalent of 139-143 g/eq and expressed by Formula (2)

(Inorganic Filler)
FB-SSDC manufactured by Denka Co. Ltd., spherical fused silica having a mean particle size of 4.1 μm

(Curing Accelerator)
2-ethyl-4-methylimidazole (2E4MZ)

[Evaluation Tests]

The respective epoxy resin compositions were subjected to the following evaluation tests. The results of the evaluation tests are summarized in the following Table 1.

(Viscosity)

The viscosities of the respective epoxy resin compositions were measured at room temperature (of 25° C.) using a B-type viscometer.

(Breaking Elongation)

A dumbbell-shaped test specimen (having a thickness of 50 μm, type 6, and a parallel portion with a width of 4 mm and a length of 25 mm) was formed out of each epoxy resin composition. Next, the test specimen was subjected to a tensile test using a tensile tester compliant with ISO 3384 (Autograph AGS-X manufactured Shimadzu Corporation) at a tensile rate of 25 mm/min to obtain a breaking elongation.

(Moisture Vapor Transmission Rate)

A test specimen was formed out of each epoxy resin composition compliant with annex B of JIS K7129 and had its moisture vapor transmission rate measured.

TABLE 1

| | | | | | | | Comparative |
|---|---|---|---|---|---|---|---|
| | | Examples | | | | | example |
| | | 1 | 2 | 3 | 4 | 5 | 1 |
| Epoxy resin | Epoxy resin 1 | 54 | 27 | 67 | 13.5 | 20 | 0 |
| | Epoxy resin 2 | 0 | 0 | 0 | 0 | 7 | 21 |
| Curing agent | | 24 | 12 | 31 | 6 | 12 | 18 |
| Inorganic filler | | 20 | 60 | 0 | 80 | 60 | 60 |
| Curing accelerator | | 2 | 1 | 2 | 0.5 | 1 | 1 |
| Total | | 100 | 100 | 100 | 100 | 100 | 100 |
| Viscosity | Pa · s | 1 | 5 | 0.2 | 100 | 13 | 30 |
| Breaking elongation | % | 400 | 230 | 410 | 50 | 200 | 10 |
| Moisture vapor | g/(m² · 24 h) | 26 | 20 | 45 | 15 | 21 | 24 |
| transmission rate | | | | | | | |

### REFERENCE SIGNS LIST

1 Resin-Encapsulated Substrate

2 Substrate

3 Electronic Component

4 Encapsulating Resin Layer

1. An epoxy resin composition comprising an epoxy resin and a curing agent, the epoxy resin including an epoxy resin expressed by the following Formula (1), 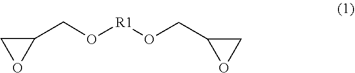
where R1 represents a divalent organic group having a carbon number of two or more,
content of the epoxy resin expressed by Formula (1) with respect to a total mass of the epoxy resin being 50% by mass or more,
the curing agent containing a phenolic resin expressed by the following Formula (2): 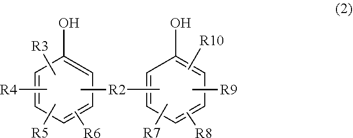
where R2 represents a divalent organic group having a carbon number of one or more and R3-R10 each independently represent a hydrogen atom, a hydroxyl group, or an allyl group.

2. The epoxy resin composition of claim 1, further containing an inorganic filler.

3. The epoxy resin composition of claim 2, wherein
content of the inorganic filler with respect to the total mass of the epoxy resin composition is 70% by mass or less.

4. The epoxy resin composition of claim 1, wherein
a molded product of the epoxy resin composition has a breaking elongation of 30% or more.

5. The epoxy resin composition of claim 1, wherein
the epoxy resin composition is used to encapsulate an electronic component mounted on a substrate.

6. A resin-encapsulated substrate comprising: a substrate; an electronic component mounted on the substrate; and an encapsulating resin layer to encapsulate the electronic component,
the encapsulating resin layer being a molded product of the epoxy resin composition of claim 1.
